(19) United States
(12) Patent Application Publication
(10) Pub. No.: US 2019/0214332 A1
(43) Pub. Date: Jul. 11, 2019

(54) SERIALLY-CONNECTED TRANSISTOR DEVICE

(71) Applicant: SIRECTIFIER ELECTRONIC CO., LTD., New Taipei (TW)

(72) Inventors: Wen-Pin CHEN, New Taipei (TW); Kuo-Tung LEE, New Taipei (TW)

(21) Appl. No.: 15/867,180

(22) Filed: Jan. 10, 2018

(51) Int. Cl. H01L 23/495; H01L 29/78; H01L 29/739; H01L 25/07

(52) U.S. Cl. CPC H01L 23/49517; H01L 23/49541; H01L 25/072; H01L 29/78; H01L 29/7393; H01L 23/49575

(57) ABSTRACT

The present disclosure illustrates to a serially-connected transistor device including a lead line frame including a carrier board and an electrode pin set, and the carrier board including a first board and a second board, and the electrode pin set including a first pin electrically connected to the first board, and a second pin, a third pin and a fourth pin; and a die unit including a first die and a second die electrically connected to the first board and the second board, respectively, so that two transistors can be electrically connected in series in the serially-connected transistor device to increase reverse voltage. As a result, the serially-connected transistor device of the present disclosure can be produced by automation die bonding and wire bonding manner, so as to achieve the effect of automated production, high yield, low cost, and better product consistency and reliability.

### BACKGROUND OF THE INVENTION

### 1. Field of the Invention

The present disclosure relates to a serially-connected transistor device. More particularly, the serially-connected transistor device of the present disclosure includes a die unit including a first die and a second die which are disposed on a lead line frame, and two transistors can be electrically connected in series in the serially-connected transistor device of the present disclosure to increase reverse voltage; furthermore, the serially-connected transistor device of the present disclosure can be produced by automation die bonding and wire bonding manner, so as to achieve the effect of high yield, low cost, and better product consistency and reliability.

### 2. Description of the Related Art

In power semiconductor component design, package and test fields, the technologies of discrete device and packaged device for parallel connection are fully developed and widely applied, but the application of serial connection of device is hard to be widely applied because of lacking a practical and automated-manufacturing solution having low cost and high reliability. For this reason, the serially-connected devices are not popular and may be less widely applied. The manipulation of connecting multiple devices in parallel is to add the current flowing through the devices, and the manipulation of connecting multiple devices in series is to add the voltages across the devices. When the devices are operated under a fixed power, the higher operation voltage can effectively decrease the operation currents flowing through the devices, so as to achieve effect of high efficiency and energy saving, and to satisfy the requirement in high-power density. While the device is operated under the same power, when the voltage across the device is increased, the current flowing through the device can be decreased because of the power equal to product of the voltage and the current (P=V*I), so as to lower a current specification of the end products using the semiconductor device, improve the power density of the end product; furthermore, because the semiconductor component using lower current can have a smaller size and lower cost, the cost of the end product can also be reduce.

Generally, a tripolar transistor has three electrodes, such as a collector C, a gate G and an emitter E; or a drain D, a gate G and a source S. However, there is no serial-connection technology developed for the conventional tripolar transistor, so only power module having larger size, very low power density and failing in automated production, exists in market. Therefore, what is needed is to develop a technical solution to solve the problems that the manufacturing process of conventional tripolar transistor is complicated and unable to use fully automatic processing manner, and the conventional tripolar transistors have bad product consistency and reliability.

### SUMMARY OF THE INVENTION

In order to solve above-mentioned problems, the present disclosure is to provide serially-connected transistor device.

An objective of the present disclosure is to provide a serially-connected transistor device including a lead line frame including a carrier board and an electrode pin set, and the carrier board includes a first board and a second board, the electrode pin set includes a first pin electrically connected to the first board, and a second pin, a third pin and a fourth pin which are independently disposed. A die unit includes a first die and a second die, first electrodes of the first die and the second die are electrically connected to the first board and the second board, respectively; second electrodes of the first die and the second die are electrically connected to the second pin and the third pin, respectively. When the first die and the second die are insulated-gate bipolar transistor (IGBT) dies, a third electrode of the first die is electrically connected to the second board; when the first die and the second die are

MOSFET dies, the third electrode of the first die is electrically connected to the first electrode of the second die, and the third electrode of the second die is electrically connected to the fourth pin. As a result, the manner of electrically connecting the two tripolar transistors in series can increase reverse voltage, so as to achieve the effect of automated production, high yield, low cost and better product consistency and reliability.

Other objective of the present disclosure is that the second electrodes of the first die and the second die of the die unit are used to control the gates of the two transistors to turn on or off at the same time, so that the serially-connected transistor device of the present disclosure can have double amplitude of the operation voltage and be applicable to the power supply circuit operating under higher operation voltage; furthermore, after the operation voltage is increased, the power supply circuit operating under the same power can decrease the current flowing therethrough, so that the integration design of connecting two tripolar transistors in series can lower the current specification of the end product using the semiconductor device, thereby improving power density, reducing size, and effectively decreasing cost.

Another objective of the present disclosure is that the die unit may include the third die and the fourth die which are flyback diode dies, and each of the third die and the fourth die includes the first electrode formed at a back surface thereof and the second electrode formed at a front surface thereof, and the first electrode of the third die and the first electrode of the fourth die are connected to the first board and the second board, respectively, and the second electrode of the third die is electrically connected to the second board through a lead line, the second electrode of the fourth die is electrically connected to the fourth pin of the electrode pin set through a lead line; when the power supply circuit turns off the first die and the second die of an inductive load, the first die and the second die connected in parallel with the third die and the fourth die, which both are flyback diodes, can deplete or release the back electromotive force or the surge voltage by current, to achieve the effect of smoothing current, thereby preventing occurrence of the surge voltage and protecting the tripolar transistor or other circuit component.

Another objective of the present disclosure is that the electrode pin set of the lead line frame includes a fifth pin electrically connected to the second board and served as the test electrode for voltage division of the two serially-connected tripolar transistors, and the first pin and the second pin in cooperation with the fifth pin are served as the first set of test pins; and the third pin, the fourth pin and the fifth pin are served as the second set of test pins, so that the resistance, the electrical characteristics, the practical voltage distribution during operation of each of the first die and the second die can be tested individually, so that the product reliability of the serially-connected transistor device is excellent.

Alternative objective of the present disclosure is that the serially-connected transistor device of the present disclosure can be manufactured by using the die bonding and wire bonding manner of the automation equipment, and the first die and the second die of the die unit packaged in the same module are selected from the two dies located on the same wafer and adjacent to each other, and such two dies have the closest resistances and the electrical characteristics and highest consistency, so as to provide highest reliability for the accumulated voltage application; furthermore, the plurality of packaged serially-connected transistor devices of the present disclosure can be electrically connected to the same connection plate of material parts to prevent from being scattered, to facilitate automated production; furthermore, after the packaged serially-connected transistor devices are encapsulated and molded by the outer insulative protective layer, the encapsulated product is cut into individual devices by the cutting mold, so that the technical solution of the present disclosure can be widely applied to automated productions of various tripolar transistors, thereby achieving the effect of improving production efficiency and yield, and lowering cost.

### BRIEF DESCRIPTION OF THE DRAWINGS

The structure, operating principle and effects of the present disclosure will be described in detail by way of various embodiments which are illustrated in the accompanying drawings.

FIG. 1 is a schematic structural view of a preferred embodiment of the present disclosure.

FIG. 2 is an equivalent circuit diagram of two IGBTs connected in series, in accordance with the present disclosure.

FIG. 3 is a schematic view of arrangement of lead line frames of a preferred embodiment of the present disclosure.

FIG. 4 is a schematic view of the automated production of connecting and encapsulating lead line frames and the transistors, in accordance with the present disclosure.

FIG. 5 is a schematic structural view of other preferred embodiment of the present disclosure.

FIG. 6 is an equivalent circuit diagram of two serially-connected IGBTs electrically connected in parallel with two flyback diode, in accordance with the present disclosure.

FIG. 7 is a schematic structural view of another preferred embodiment of the present disclosure.

FIG. 8 is an equivalent circuit diagram of two MOSFETs connected in series, in accordance with the present disclosure.

FIG. 9 is a schematic structural view of alternative preferred embodiment of the present disclosure.

FIG. 10 is an equivalent circuit diagram of two serially-connected MOSFETs electrically connected in parallel with flyback diodes, in accordance with the present disclosure.

### DETAILED DESCRIPTION OF THE PREFERRED EMBODIMENTS

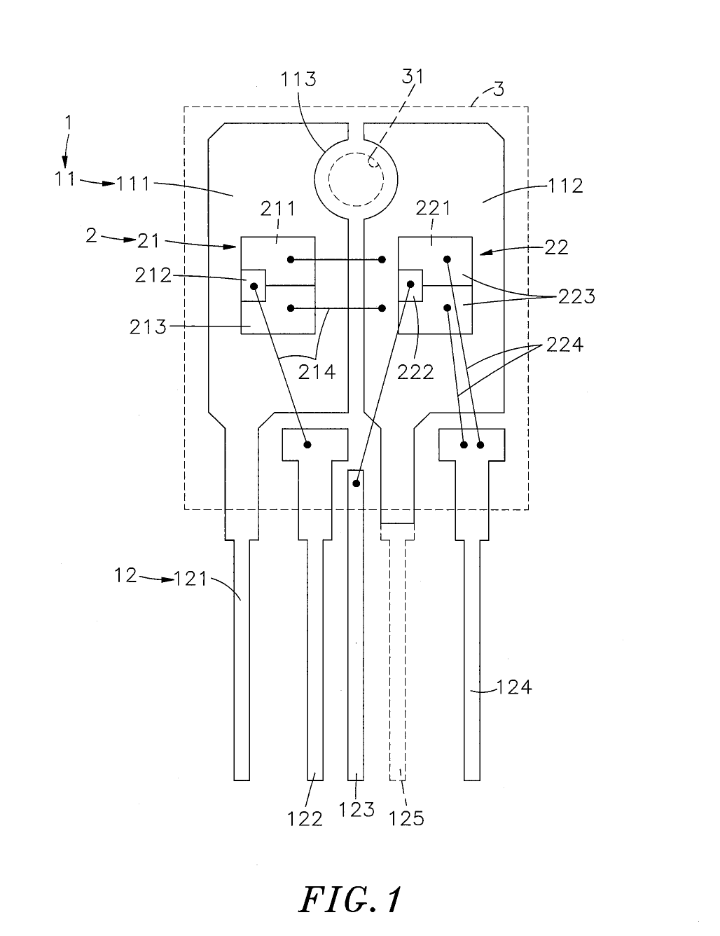

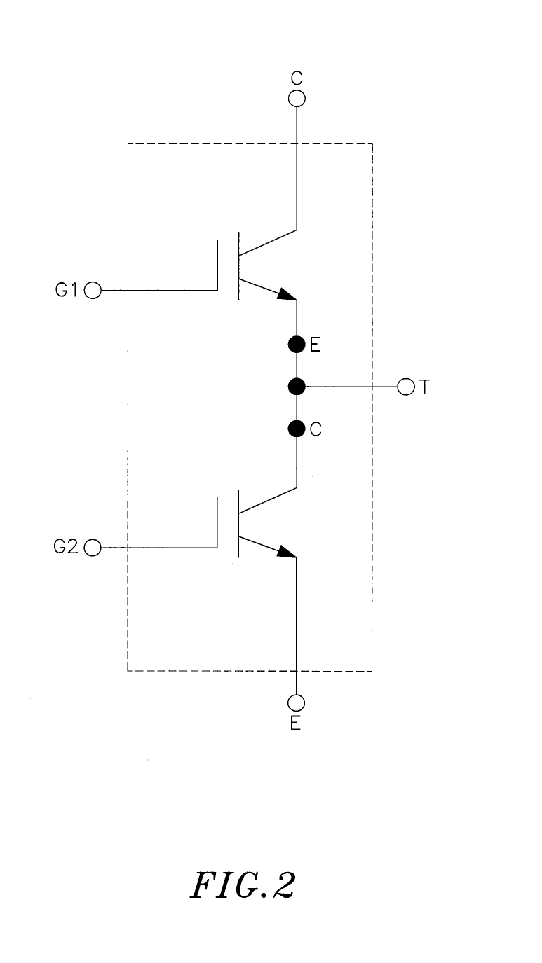

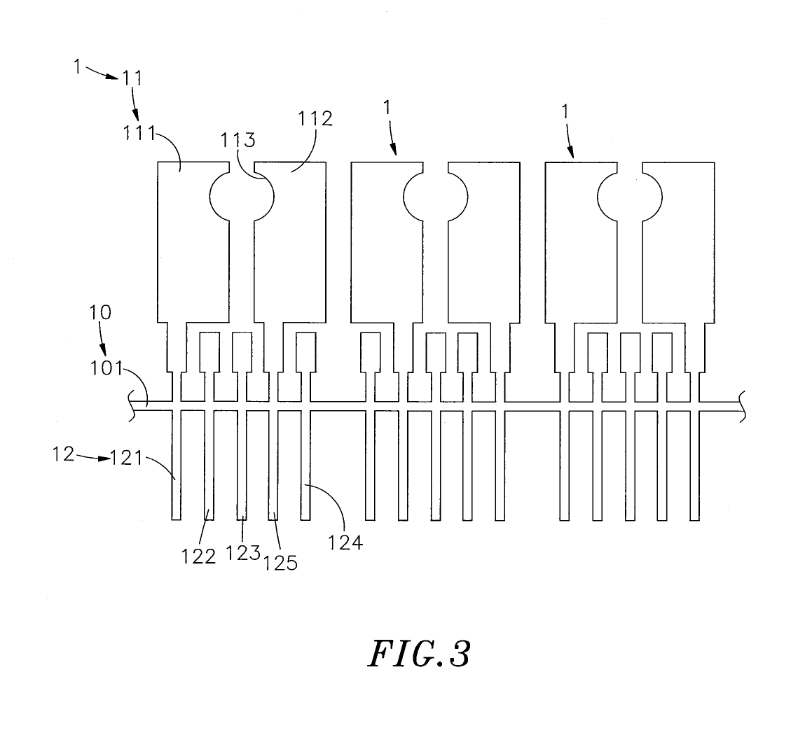

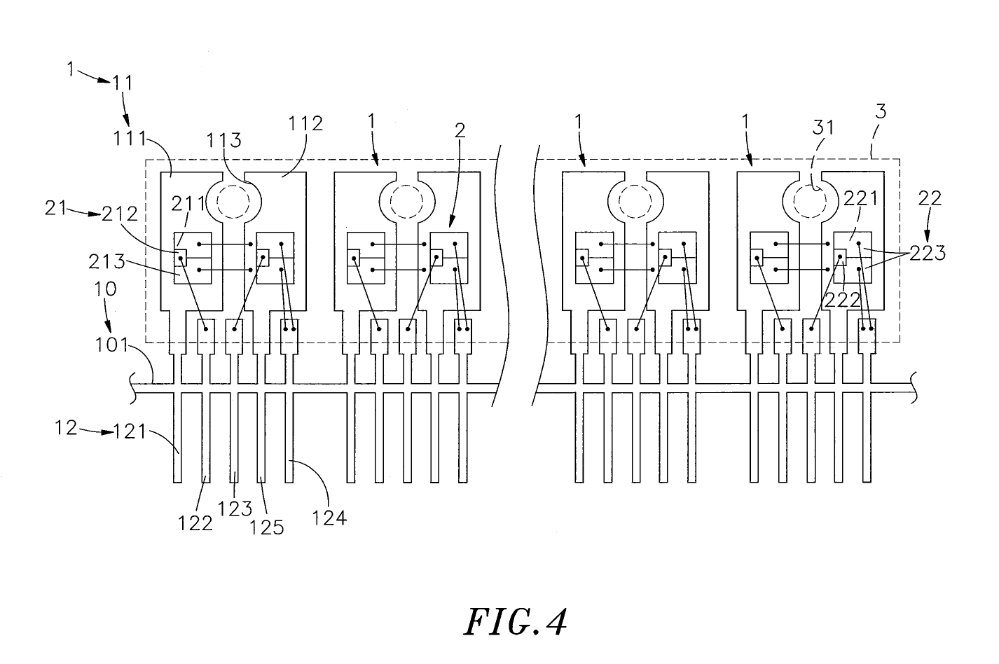

Please refer to FIGS. 1 through 4. FIG. 1 is a schematic structural view of a preferred embodiment of the present disclosure; FIG. 2 is an equivalent circuit diagram of two IGBTs connected in series, in accordance with the present disclosure; FIG. 3 is a schematic view of arrangement of lead line frames of an preferred embodiment of the present disclosure; and FIG. 4 is a schematic view of automated production of connection and encapsulation of lead line frames and the transistors, in accordance with the present disclosure, the serially-connected transistor device of the present disclosure includes a lead line frame 1, a die unit 2 and an outer insulative protective layer 3.

The lead line frame 1 is made by conductive material, and includes a carrier board 11 and an electrode pin set 12. The die unit 2 is disposed on the carrier board 11. The carrier board 11 includes a first board 111 and a second board 112 insulated from the first board 111.

The electrode pin set 12 includes a first pin 121 directly extended from or electrically connected to the first board 111, and a second pin 122, a third pin 123 and a fourth pin 124 which are independently disposed, and a fifth pin 125 directly extended from or electrically connected to the second board 112. It is to be noted that the fifth pin 125 is a pin for test, and the design of the device of the present disclosure can be changed when the test pin is not necessary; for example, the fifth pin 125 of a five-pin structure can be cut to form a four-pin structure. The position of each pin can be optimally determined according to entire connection structure of material parts 10, to facilitate production of the serially-connected transistor devices by using the automation die bonding and wire bonding manner. These embodiments will be described in following content.

The die unit 2 includes a first die 21 and a second die 22 which both are insulated-gate bipolar transistor (IGBT) dies, the first die 21 and the second die 22 respectively includes first electrodes 211, 221 formed at a back surface thereof and served as a collector C of the serially-connected transistor device, the first die 21 and the second die 22 respectively includes second electrodes 212, 222 formed at a front surface thereof and respectively served as gates G1, G2 of the serially-connected transistor device, and the first die 21 and the second die 22 respectively includes third electrodes 213, 223 formed at a front surface thereof and served as an emitter E of the serially-connected transistor device. The first die 21 and the second die 22 are disposed on the carrier board 11 and connected to the first board 111 and the second board 112 through the first electrodes 211 and 221, respectively. The second electrodes 212 and 222 are electrically connected to the second pin 122 and the third pin 123 of the electrode pin set 12 through lead lines 214 and 224, respectively. The two third electrodes 213 of the first die 21 are electrically connected to the second board 112 through the lead lines 214, respectively, and the two third electrodes 223 of the second die 22 are electrically connected to the fourth pin 124 of the electrode pin set 12 through the lead lines 224, respectively.

In this embodiment, the two third electrodes 213 of the first die 21 are electrically connected to the first electrode 221 of the second die 22 through the lead lines 214 and the second board 112 of the carrier board 11, so the fifth pin 125 extended out from the second board 112 can be served as the test electrode T of the serially-connected transistor device. The first pin 121 and the second pin 122 of the electrode pin set 12 are in cooperation with the fifth pin 125 to form a first set of test pins, and the third pin 123, the fourth pin 124 and the fifth pin 125 can form a second set of test pins, so that the resistance, the electrical characteristics, and the practical voltage distribution during operation of each of the first die 21 and the second die 22 can be individually tested, thereby providing excellent product reliability.

The outer insulative protective layer 3 is made by epoxy resin or other plastic material, and formed as one-piece disposed on the carrier board 11 of the lead line frame 1 to cover the die unit 2. In other embodiment, the lead line frame 1 can include a heat sink exposed out and not covered by the outer insulative protective layer 3, so as to efficiently dissipate heat from the first die 21 and the second die 22. In other embodiment, a back part of the carrier board 11 can be in contact with outside air directly for heat dissipation, or an exposed structure of the carrier board 11 other than the electrode pin set 12 and not enclosed by the outer insulative protective layer 3 can be in contact with outside air directly for heat dissipation.

As shown in FIGS. 3 and 4, the material parts 10 of this embodiment is processed to form the carrier boards 11 and the electrode pin sets 12 of the plurality of lead line frames 1, and a connection plate 101 can be formed at the electrode pin sets 12 to horizontally connect the electrode pin sets 12. When the serially-connected transistor devices of the present disclosure are produced by the die bonding and wire bonding manner of the automation equipment, the first die 21 and the second die 22 of the die unit 2 of the same packaged device are selected from two dies located on the same wafer and adjacent to each other, and the first die 21 and the second die 22 of the die unit 2 are connected in series, so that the first die 21 and the second die 22 can have the closest resistance and the closest electrical characteristics and highest consistency, so as to provide highest reliability for the application of connecting the devices in series to add the across voltage; furthermore, the plurality of packaged devices are connected by the connection plate 101 of the material parts 10, so that whole structure of the packaged devices does not scatter and facilitate automated production; the intervals between the first boards 111 and the second boards 112 of the serially-connected transistor devices can be kept the same, and after the serially-connected transistor devices are encapsulated and molded by the outer insulative protective layer 3, the encapsulated product can be cut into individual devices by the cutting mold, so as to achieve the effect of improving production efficiency and yield, and lowering cost.

Furthermore, the first board 111 and the second board 112 of the carrier board 11 can have almost the same orthographic projection areas, so that the heat dissipation performance of the first board 111 for the first die 21 is almost the same as that of the second board 112 for the second die 22, thereby preventing inconsistency in temperatures of the first die 21 and the second die 22 during operation, and further preventing difference in the electrical characteristics of the first die 21 and the second die 22. Each set of the first board 111 and the second board 112 includes an arc-shaped notched grooves 113 formed at relatively inner side thereof, and the outer insulative protective layer 3 is formed with a locking hole 31 cut through a surface thereof and passing through the two notched grooves 113, so that a fastener, such as a screw, can be inserted through the locking hole 31, to fasten the serially-connected transistor device on other object, such as a heat sink or a circuit board.

In this embodiment, the first die 21 and the second die 22 of the die unit 2 are connected in series, the second electrode 212 of the first die 21 and the second electrode 222 of the second die 22 are electrically connected to the second pin 122 and the third pin 123 of the electrode pin set 12, respectively. The second pin 122 and the third pin 123 are independently disposed in the electrode pin set 12, to control switching the gates G1 and G2 of the two IGBTs simultaneously, to double the amplitude operation voltage of device, for example, the first die 21 and the second die 22 are IGBTs which each has 1700V withstand voltage, so that the serially-connected transistor device can have a 3400V withstand voltage higher than that of single packaged IGBT chip and be applicable to the power supply circuit operating under higher operation voltage. Under a condition that the power supply circuit provides the same power, after the operational voltage of the device is increased, the current flowing through the device can be decreased, so that the integration design of two serially-connected IGBTs device of the present disclosure can lower the current specification of the end product using the semiconductor device, and improve the power density of the end product; furthermore, the semiconductor device using lower current can have smaller size, so the cost of the end products can be reduced.

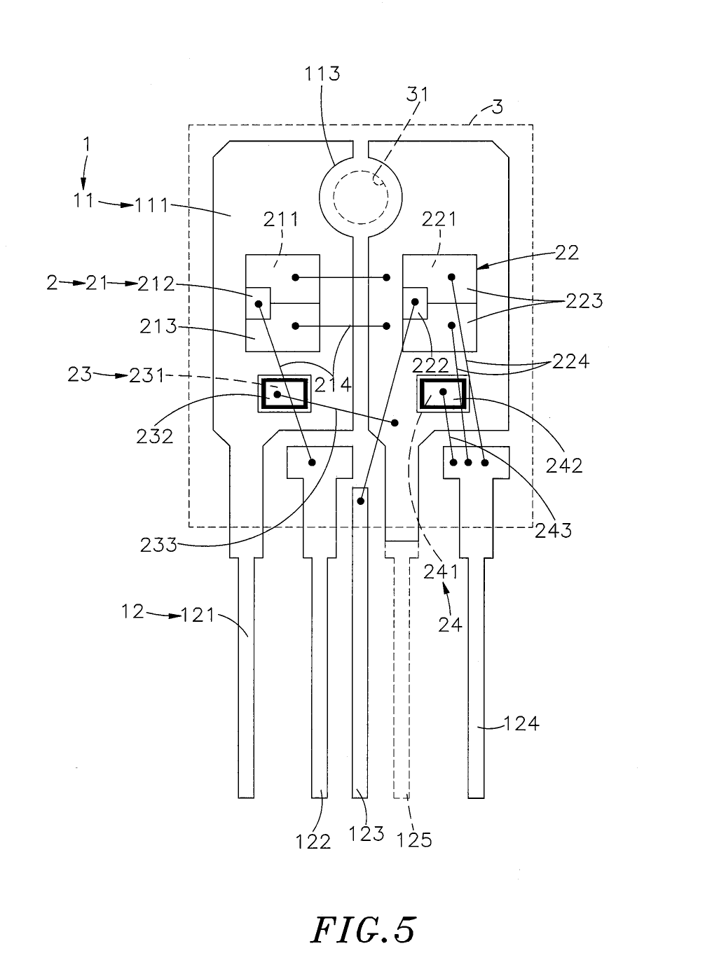

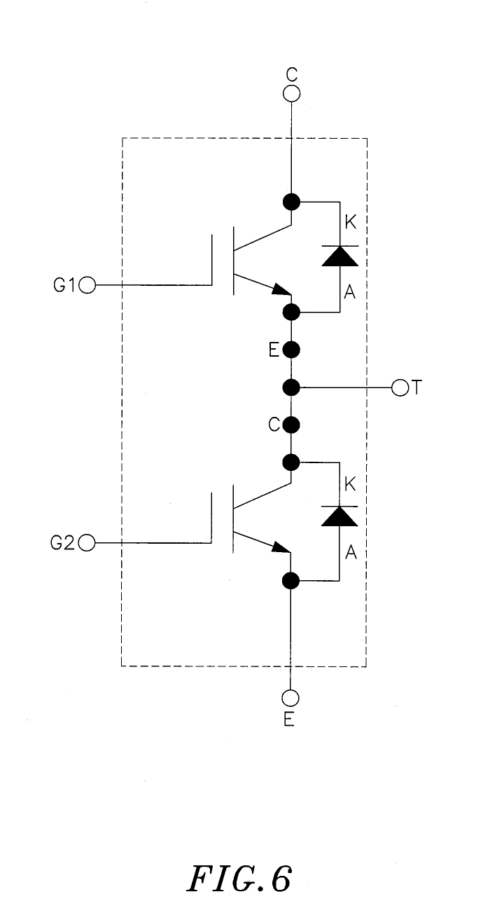

Please refer to FIGS. 5 and 6. FIG. 5 is a schematic structural view of other preferred embodiment of the present disclosure, and FIG. 6 is an equivalent circuit diagram of the two serially-connected IGBTs electrically connected in parallel with two flyback diodes. In this embodiment, the die unit 2 includes a third die 23 and a fourth die 24 which both are flyback diode dies, respectively. The flyback diode (or freewheeling diode) is generally implemented by a fast recovery diode or a Schottky diode. The third die 23 and the fourth die 24 respectively includes first electrodes 231, 241 formed at a back surface thereof and served as a cathode K of the diode, and second electrodes 232, 242 formed on a front surface and served as an anode A of the diode. The third die 23 arid the fourth die 24 are connected to the first board 111 and the second board 112 through the first electrodes 231 and 241, respectively, so that the second electrode 232 of the third die 23 can be electrically connected to the second board 112 through a lead line 233, and electrically connected to the first electrode 211 of the second die 22 through the second board 112; the second electrode 242 of the fourth die 24 is electrically connected to the fourth pin 124 of the electrode pin set 12 through a lead line 243, so that two end electrodes of each of the IGBTs is electrically connected in parallel with the flyback diode.

When the power supply circuit turns off the first die 21 and the second die 22 of the inductive load such as a relay or inductor coil, the inductive load generates a back electromotive force or a surge voltage, which may be up to more than 1000V, at two ends thereof, and the extra-high voltage may easily cause the tripolar transistor (such as IGBT, MOSFET or other circuit component) to breakdown. For this reason, the first die 21 and the second die 22 are electrically connected in parallel with the third die 23 and the fourth die 24 which both are the flyback diodes, to deplete or release the back electromotive force or the surge voltage by current, to achieve the effect of smoothing current, and thereby preventing occurrence of the surge voltage and protecting the tripolar the transistor or other circuit component.

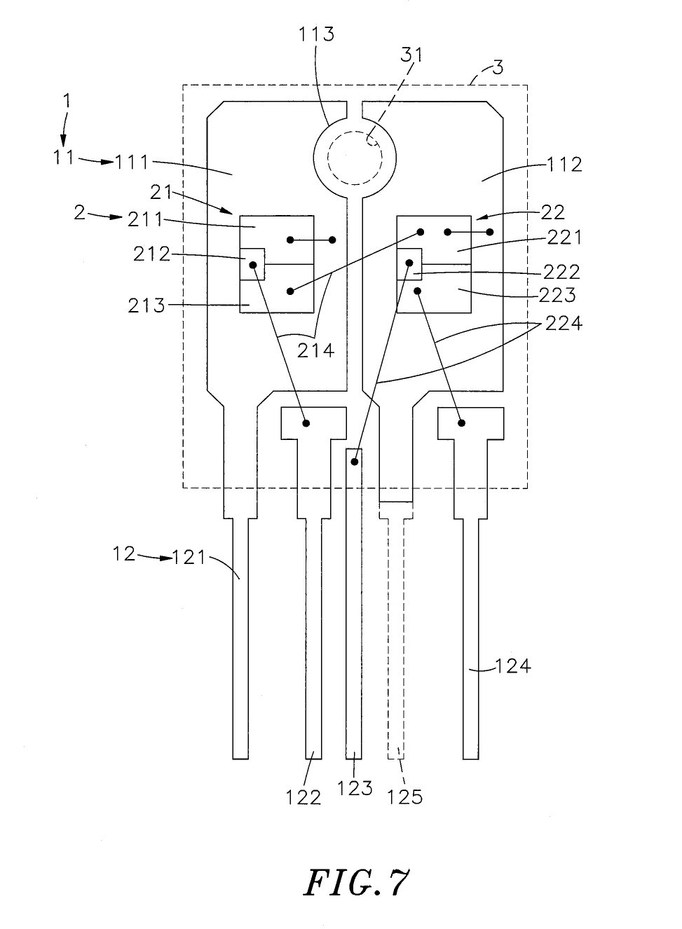

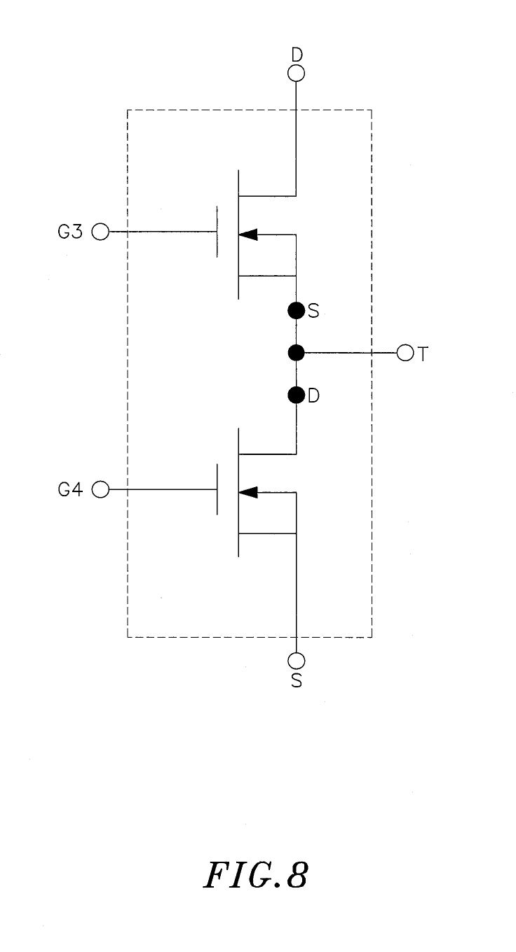

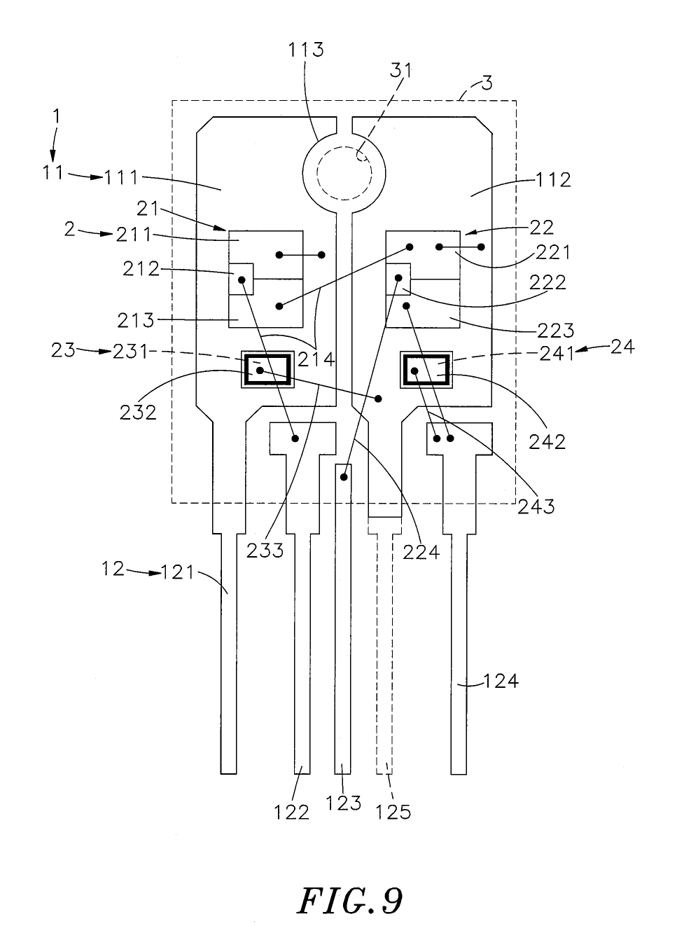

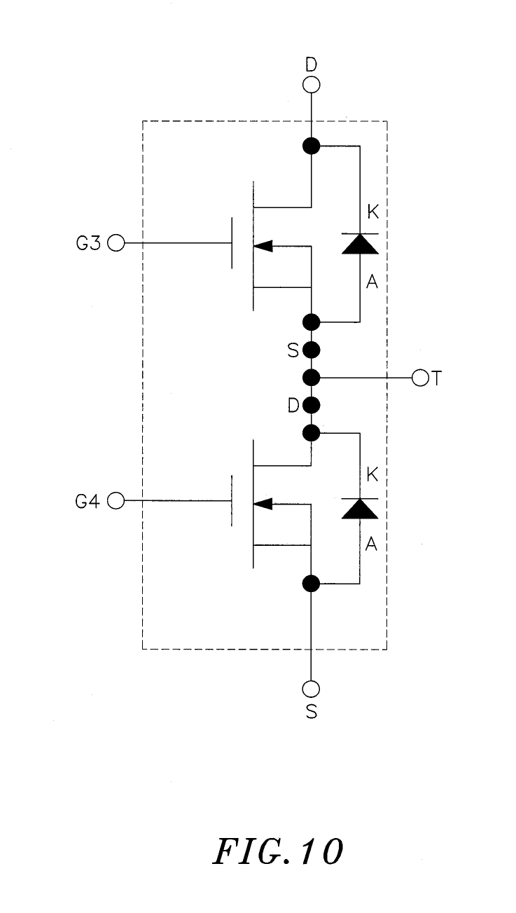

Please refer to FIGS. 7 through 10. FIG. 7 is a schematic structural view of another preferred embodiment of the present disclosure, FIG. 8 is an equivalent circuit diagram of two MOSFETs electrically connected in series, in accordance with the present disclosure, FIG. 9 is a schematic structural view of alternative preferred embodiment of the present disclosure, and FIG. 10 is an equivalent circuit diagram of two serially-connected MOSFETs electrically connected in parallel with two flyback diodes, in accordance with the present disclosure. The present disclosure further provides a serially-connected transistor device including the lead line frame 1, the die unit 2 and the outer insulative protective layer 3 described in one of aforementioned embodiments. The difference between the die unit 2 of this embodiment and the die unit 2 of FIG. 1 is that the first die 21 and the second die 22 of this embodiment are MOSFET dies, and the first die 21 and the second die 22 have the first electrodes 211 and 221 formed at the front surfaces thereof, respectively, and served as a drain D of the serially-connected transistor device; the first die 21 and the second die 22 respectively includes second electrodes 212, 222 formed at the front surface thereof, respectively and served as gates G3, G4 of the serially-connected transistor device, and the first die 21 and the second die 22 respectively includes third electrodes 213, 223 formed at the front surface thereof and served as a source S of the serially-connected transistor device. The back surfaces of the first die 21 and the second die 22 are disposed on but not connected to the carrier board 11. The first electrode 211 of the first die 21 is electrically connected to the first board 111 through the lead line 214, the second electrode 212 and the third electrode 213 are electrically connected to the second pin 122 of the electrode pin set 12 and the first electrode 221 of the second die 22 through the lead line 214, respectively. The first electrode 221 of the second die 22 is electrically connected to the second board 112 through the lead line 224, and the second electrode 222 and the third electrode 223 are electrically connected to the third pin 123 and the fourth pin 124 of the electrode pin set 12 through the lead line 224, respectively.

In this embodiment, the third electrode 213 of the first die 21 is electrically connected to the second board 112 of the carrier board 11 through the lead line 214, the first electrode 221 of the second die 22 and the lead line 224, so that the fifth pin 125 extended out from the second board 112 can be served as the test electrode T of the serially-connected transistor device; the first pin 121, the second pin 122 and the fifth pin 125 of the electrode pin set 12 are served as the first set of the test pins, the third pin 123, the fourth pin 124 and the fifth pin 125 form the second set of the test pins, so as to individually test the resistance, the electrical characteristics, and the practical voltage distribution during operation of each of the first die 21 and the second die 22, thereby providing excellent product reliability.

In this embodiment, the first die 21 and the second die 22 of the die unit 2 are connected in series, the second electrode 212 of the first die 21 and the second electrode 222 of the second die 22 are electrically connected to the second pin 122 and the third pin 123 of the electrode pin set 12, respectively, so as to control switching of the gates G3 and G4 of the two MOSFETs simultaneously, so that the serially-connected transistor device of the present disclosure can have the withstand voltage with double amplitude higher than the withstand voltage of the packaged single MOSFET chip, and the serially-connected transistor device is applicable to the power supply circuit operating under higher operation voltage; however, the actual application of the present disclosure is not limited to above examples. The first die 21 and the second die 22 can be two BJTs, two JEFTs, or other tripolar transistors which are electrically connected in series. Under a condition that the power supply circuit provides the same power, when the operational voltage of the device is increased, the operational current flowing through the device can be decreased, so that the integrated structural design of connecting two tripolar transistors of the present disclosure can lower the current specification of the end product using the semiconductor device, so as to improve the power density of the end product and effectively decrease cost of the end product.

As shown in FIGS. 9 and 10, the die unit 2 of this embodiment includes the third die 23 and the fourth die 24 of one of aforementioned embodiments, and the third die 23 and the fourth die 24 are flyback diode dies which can be implemented by fast recovery diodes or Schottky diodes. The third die 23 and the fourth die 24 respectively includes the first electrodes 231 and 241 formed at the back surfaces thereof and served as the cathode K of the diode, the second electrodes 232 and 242 formed on the front surfaces thereof and served as the anode A of the diode, and the third die 23 and the fourth die 24 are connected to the first board 111 and the second board 112 through the first electrodes 231 and 241, respectively, so that the second electrode 232 of the third die 23 can be electrically connected to the second board 112 through the lead line 233, and electrically connected to the first electrode 211 of the second die 22 through the second board 112. The second electrode 242 of the fourth die 24 is electrically connected to the fourth pin 124 of the electrode pin set 12 through the lead line 243. As a result, each of the serially-connected MOSFETs is also electrically connected in parallel with a flyback diode by two end electrodes thereof.

When the power supply circuit turns off the first die 21 and the second die 22 of the inductive load, the inductive load generates the back electromotive force or the surge voltage at two ends thereof, the first die 21 and the second die 22 is electrically connected in parallel with one of the third die 23 and the fourth die 24 having the flyback diodes, respectively, so that the flyback diode can deplete or release the back electromotive force or the surge voltage by current, to achieve the effect of smoothing current, thereby effectively preventing occurrence of the surge voltage and protecting the tripolar transistor or other circuit component.

The main concept of the present disclosure is that the lead line frame 1 includes the carrier board 11 and the electrode pin set 12, the die unit 2 is disposed on the carrier board 11, the first electrodes 211 and 221 of the first die 21 and the second die 22 are electrically connected to the first board 111 and the second board 112, respectively; the electrode pin set 12 includes the first pin 121 electrically connected to the first board 111, and the second electrodes 212 and 222 of the first die 21 and the second die 22 are electrically connected to the second pin 122 and the third pin 123 of the electrode pin set 12, respectively; the third electrode 213 of the first die 21 is electrically connected to the second board 112 or the first electrode 221 of the second die 22, the third electrode 223 of the second die 22 is electrically connected to the fourth pin 124 of the electrode pin set 12, so that the integration structural design of serially-connected tripolar transistors can increase the reverse voltage, so as to achieve the effect of automated production, high yield, low cost, and better product consistency and reliability.

The present disclosure disclosed herein has been described by means of specific embodiments. However, numerous modifications, variations and enhancements can be made thereto by those skilled in the art without departing from the spirit and scope of the disclosure set forth in the claims.

What is claimed is:

1. A serially-connected transistor device, comprising:
a lead line frame made by conductive material and comprising a carrier board and an electrode pin set, said carrier board comprising a first board and a second board insulated from said first board, said electrode pin set comprising a first pin, a second pin, a third pin and a fourth pin, wherein said second pin, said third pin and said fourth pin are disposed independently, and said first pin is electrically connected to said first board;
a die unit comprising a first die and a second die, and said first die and said second die respectively comprising first electrodes formed at a back surface thereof and served as a collector of the serially-connected transistor device, said first die and said second die respectively comprising second electrodes formed at a front surface thereof and served as gates of the serially-connected transistor device, and said first die and said second die comprising third electrodes formed at a front surface thereof and served as an emitter of the serially-connected transistor device, wherein said first die and said second die are disposed on said carrier board and connected to said first board and said second board through said first electrodes thereof, respectively, and said second electrodes of said first die and said second die are electrically connected to said second pin and said third pin, respectively, and said third electrode of said first die is electrically connected to said second board, and said third electrode of said second die is electrically connected to said fourth pin; and
an outer insulative protective layer disposed on said lead line frame and configured to cover said die unit, wherein said electrode pin set is exposed out of said outer insulative protective layer.

2. The serially-connected transistor device according to claim 1, wherein said first die and said second die of said die unit are insulated-gate bipolar transistor (IGBT) dies, said second electrode of said first die and said second electrode of said second die are electrically connected to said second pin and said third pin of said electrode pin set through a lead line, respectively, and said first die comprises two third electrodes electrically connected to said second board through said lead lines, respectively, and said second die comprises two said third electrodes electrically connected to said fourth pin through said lead lines, respectively.

3. The serially-connected transistor device according to claim 2, wherein said electrode pin set comprises a fifth pin directly extended from or electrically connected to said second board, and served as a test electrode of the serially-connected transistor device;
wherein a first pin and said second pin, in cooperation with said fifth pin, are served as a first set of die test pins;
wherein said third pin and said fourth pin, in cooperation with said fifth pin, are served as a second set of die test pins.

4. The serially-connected the transistor device according to claim 1, wherein said die unit comprises a third die and a fourth die which are flyback diode dies, said third die and said fourth die respectively comprises first electrodes formed at a back surface thereof and served as a cathode of the diode, and second electrodes formed on a front surface thereof and served as an anode of the diode, and said first electrode of said third die and said first electrode of said fourth die are connected to said first board and said second board, respectively, and said second electrode of said third die is electrically connected to said second board through a lead line, said second electrode of said fourth die is electrically connected to said fourth pin of said electrode pin set through a lead line, and said first die and said second die are connected in parallel with said third die and said fourth die, respectively.

5. The serially-connected transistor device according to claim 4, wherein said third die and said fourth die of said die unit uses a fast recovery diode or a Schottky diode, as the flyback diode.

6. The serially-connected transistor device according to claim 1, wherein the orthographic projection area of said first board is almost the same as that of said second board.

7. The serially-connected transistor device according to claim 1, further comprising a connection plate formed by material parts and at said electrode pin set and configured to horizontally connect said lead line frames;
wherein after the serially-connected transistor devices are produced by automation die bonding and wire bonding manner and encapsulated and molded by said outer insulative protective layer, the encapsulated product is cut into individual serially-connected transistor devices by the cutting mold.

8. The serially-connected transistor device according to claim 7, wherein a first die and a second die of a die unit are selected from two dies located on the same wafer and adjacent to each other.

9. A serially-connected transistor device, comprising:
a lead line frame made by conductive material and comprising a carrier board and an electrode pin set, said carrier board comprising a first board and a second board insulated from said first board, and said electrode pin set comprising a first pin, a second pin, a third pin and a fourth pin, wherein said second pin, said third pin and said fourth pin are disposed independently, and said first pin is electrically connected to said first board;
a die unit comprising a first die and a second die, said first die and said second die comprising first electrodes formed on a front surface thereof, respectively, and served as a drain of the serially-connected transistor device, and second electrodes formed on the front surface thereof, respectively, and served as gates of the serially-connected transistor device, and third electrodes formed on the front surface thereof, respectively, and served as a source of the serially-connected transistor device, and back surfaces of said first die and said second die are disposed on said first board and said second board of said carrier board, respectively, said first electrode of said first die is electrically connected to said first board, said second electrode and said third electrode of said first die are electrically connected to said second pin and said first electrode of said second die, respectively, and said first electrode of said second die is electrically connected to said second board, said second electrode and said third electrode of said second die are electrically connected to said third pin and said fourth pin, respectively; and
an outer insulative protective layer disposed on said lead line frame and configured to cover said die unit, wherein said electrode pin set is exposed out of said outer insulative protective layer.

10. The serially-connected transistor device according to claim 9, wherein said first die and said second die of said die unit are MOSFET dies, said first electrode of said first die and said first electrode of said second die are electrically connected to said first board and said second board of said carrier board through a lead line, respectively, and said second electrode and said third electrode of said first die are electrically connected to said second pin of said electrode pin set and said first electrode of said second die through said lead line, respectively, and said second electrode and said third electrode of said second die are electrically connected to said third pin and said fourth pin through said lead line, respectively.

11. The serially-connected transistor device according to claim 10, wherein said electrode pin set comprises a fifth pin directly extended from or electrically connected to said second board, as a test electrode of the serially-connected transistor device;
wherein a first pin and said second pin, in cooperation with said fifth pin, are served as a first set of die test pins;
wherein said third pin and said fourth pin, in cooperation with said fifth pin, are served as a second set of die test pins.

12. The serially-connected the transistor device according to claim 9, wherein said die unit comprises a third die and a fourth die which are the flyback diode dies, said third die and said fourth die respectively comprises first electrodes formed at a back surface thereof and served as a cathode of the diode, second electrodes formed on a front surface thereof and serve as an anode of the diode, wherein said first electrode of said third die and said first electrode of said fourth die are connected to said first board and said second board, respectively, and said second electrode of said third die is electrically connected to said second board through a lead line, said second electrode of said fourth die is electrically connected to said fourth pin of said electrode pin set through a lead line, wherein said first die and said second die are connected in parallel with said third die and said fourth die, respectively.

13. The serially-connected transistor device according to claim 12, wherein said third die and said fourth die of said die unit uses the fast recovery diode or the Schottky diode, as the flyback diode.

14. The serially-connected the transistor device according to claim 9, wherein the orthographic projection area of said first board is almost the same as that of said second board.

15. The serially-connected the transistor device according to claim 9, further comprising a connection plate formed by material parts and at said electrode pin set, and configured to horizontally connect said lead line frames;
wherein after the serially-connected transistor devices are produced by automation die bonding and wire bonding manner and encapsulated and molded by the outer insulative protective layer, the encapsulated product is cut into individual serially-connected transistor devices by the cutting mold.

16. The serially-connected transistor device according to claim 15, wherein a first die and a second die of a die unit are selected from two dies located on the same wafer and adjacent to each other.
